(19) United States
(12) Patent Application Publication
(10) Pub. No.: US 2026/0133268 A1
(43) Pub. Date: May 14, 2026

(54) SYSTEM AND METHOD FOR REDUCING PARASITIC HEAT LOAD FROM A NON-OPERATING CRYOCOOLER

(71) Applicant: GE Precision Healthcare LLC, Waukesha, WI (US)

(72) Inventors: Ernst Wolfgang Stautner, Niskayuna, NY (US); Anbo Wu, Clifton Park, NY (US); Vijay Kumar Soni, Niskayuna, NY (US)

(21) Appl. No.: 18/941,001

(22) Filed: Nov. 8, 2024

(51) Int. Cl. G01R 33/38

(52) U.S. Cl. CPC G01R 33/3804

(57) ABSTRACT

A superconducting machine system includes a superconducting electrical machine. The superconducting machine system also includes a cryogenic vessel. The cryogenic vessel encompasses the superconducting electrical machine. The superconducting machine system further includes a vacuum vessel wall encompassing the cryogenic vessel. The superconducting machine system even further includes a cryocooler coupled to the vacuum vessel wall, wherein the cryocooler is configured to cool the superconducting electrical machine. The superconducting machine system still further includes a system configured, when the cryocooler is switched to a non-operative state, to remove helium gas from within a cryocooler housing to reduce a helium gas pressure within the cryocooler to minimize a parasitic heat load generated when the cryocooler is switched from an operative state to the non-operative state.

### STATEMENT REGARDING FEDERALLY SPONSORED RESEARCH & DEVELOPMENT

This invention was made with US Government support under contract number U01 EB027696 awarded by the US Department of Health and Human Services National Institutes of Health. The Government has certain rights in the invention.

### BACKGROUND

The subject matter disclosed herein relates to a system and method for reducing parasitic heat load from a non-operating cryocooler.

Magnetic resonance imaging (MRI) is a medical imaging technique used in radiology to visualize detailed internal structures of a patient. MRI systems utilize a superconducting magnet to generate a strong and uniform magnetic field within which the patient is placed. The superconducting magnet consists of individual superconducting magnet coils that are placed within a cryogenic liquid to maintain their superconductivity. An MRI system includes a cryocooler which provides cooling to balance the heat load of the superconducting magnet so that no cryogen is lost. The cryocooler includes a combination of a regenerator and a displacer, to cool down and recondense the gaseous cryogen.

Whenever a cryocooler is turned off and non-operational, the resulting heat burden on the cryostat and the magnet is much higher than expected. The cause for this is the parasitic heat load that is transferred by means of highly powerful cryogenic convection currents running within the cryocooler that is transmitted through the cryocooler housing to the magnet. Superconducting machines such as motors and generators also utilize cryocoolers.

### SUMMARY

A summary of certain embodiments disclosed herein is set forth below. It should be understood that these aspects are presented merely to provide the reader with a brief summary of these certain embodiments and that these aspects are not intended to limit the scope of this disclosure. Indeed, this disclosure may encompass a variety of aspects that may not be set forth below.

In one embodiment, a superconducting machine system is provided. The superconducting machine system includes a superconducting electrical machine. The superconducting machine system also includes a cryogenic vessel. The cryogenic vessel encompasses the superconducting electrical machine. The superconducting machine system further includes a vacuum vessel wall encompassing the cryogenic vessel. The superconducting machine system even further includes a cryocooler coupled to the vacuum vessel wall, wherein the cryocooler is configured to cool the superconducting electrical machine. The superconducting machine system still further includes a system configured, when the cryocooler is switched to a non-operative state, to remove helium gas from within a cryocooler housing to reduce a helium gas pressure within the cryocooler to minimize a parasitic heat load generated when the cryocooler is switched from an operative state to the non-operative state.

In another embodiment, a system for reducing parasitic heat load from a non-operating cryocooler is provided. The system includes a cryocooler configured to couple to a vacuum vessel wall encompassing a cryogenic vessel encompassing a superconducting electrical machine, wherein the cryocooler is configured to cool the superconducting electrical machine. The system also includes a vacuum pump. The system further includes a controller including a memory and a processing system including one or more processors. The controller is configured to provide control signals to the vacuum pump, when the cryocooler is switched to a non-operative state, that cause the vacuum pump to remove helium gas from within a cryocooler housing to reduce a helium gas pressure within the cryocooler to minimize a parasitic heat load generated when the cryocooler is switched from an operative state to the non-operative state.

In a further embodiment, a method for reducing parasitic heat load from a non-operating cryocooler is provided. The method includes switching a cryocooler from an operative state to a non-operative state, wherein the cryocooler is coupled to a vacuum vessel wall encompassing a cryogenic vessel encompassing a superconducting electrical machine, and wherein the cryocooler is configured to cool the superconducting electrical machine. The method also includes utilizing a vacuum pump, when the cryocooler is switched to the non-operative state, to remove helium gas from within a cryocooler housing to reduce a helium gas pressure within the cryocooler to minimize a parasitic heat load generated when the cryocooler is switched from the operative state to the non-operative state.

### BRIEF DESCRIPTION OF THE DRAWINGS

These and other features, aspects, and advantages of the present disclosure will become better understood when the following detailed description is read with reference to the accompanying drawings in which like characters represent like parts throughout the drawings, wherein:

FIG. 1 is a simplified block diagram of a portion of a superconducting machine system, in accordance with aspects of the present disclosure;

FIGS. 2A and 2B are cross-sectional views of a portion of the superconducting machine system in FIG. 1, in accordance with aspects of the present disclosure;

FIGS. 3A and 3B are schematic diagrams of a coldhead without a coldhead sleeve attached to a liquefaction cup with inlet and outlet tube and of a coldhead without a coldhead sleeve attached to a superconducting magnet interface, respectively, in accordance with aspects of the present disclosure;

FIGS. 4A-4C are cross-sectional views of a portion of the superconducting machine system in FIG. 1 having a system for reducing parasitic heat load (e.g., via a return line), in accordance with aspects of the present disclosure;

FIG. 5 is a cross-sectional view of a portion of the superconducting machine system in FIGS. 1 and 2 having a system for reducing parasitic heat load (e.g., via the compressor), in accordance with aspects of the present disclosure;

FIG. 6 is a flow chart of an embodiment of a method for reducing parasitic heat load from a non-operating cryocooler, in accordance with aspects of the present disclosure;

FIG. 7 is a flow chart of an embodiment of a method for reducing parasitic heat load from a non-operating cryocooler (e.g., utilizing monitoring), in accordance with aspects of the present disclosure;

FIG. 8 is a flow chart of an embodiment of a method for reducing parasitic heat load from a non-operating cryocooler (e.g., utilizing set thresholds), in accordance with aspects of the present disclosure;

FIG. 9 is an example screenshot of temperatures in a cryostat and a superconducting magnet, in accordance with aspects of the present disclosure; and

FIG. 10 is a schematic diagram of an example magnetic resonance system, in accordance with aspects of the present disclosure.

### DETAILED DESCRIPTION

One or more specific embodiments will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers'specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

When introducing elements of various embodiments of the present subject matter, the articles “a,” “an,” “the,” and “said” are intended to mean that there are one or more of the elements. The terms “comprising,” “including,” and “having” are intended to be inclusive and mean that there may be additional elements other than the listed elements. Furthermore, any numerical examples in the following discussion are intended to be non-limiting, and thus additional numerical values, ranges, and percentages are within the scope of the disclosed embodiments.

While aspects of the following discussion are provided in the context of medical imaging, it should be appreciated that the disclosed techniques are not limited to such medical contexts. Indeed, the provision of examples and explanations in such a medical context is only to facilitate explanation by providing instances of real-world implementations and applications. However, the disclosed techniques may also be utilized in other contexts, such as power generation using superconducting machines. In general, the technique can be used in all superconducting machinery requiring energy transfer to/ from a much higher temperature environment. Although the disclosed techniques mention utilizing helium, another cryogen may be utilized.

The present disclosure provides a system and a method for reducing (e.g., minimizing or eliminating) parasitic heat load from a non-operating cryocooler. The cryocooler is utilized to cool a superconducting electrical machine (e.g., superconducting coils or cold mass of a magnetic resonance imaging system, motor, generator, etc.). The present disclosure applies to any machine that utilizes a superconducting wire and needs a cryocooler (e.g., rotating and non-rotating (cryocoolers included)), accelerator magnets, mine sweepers, cyclotrons, and so forth). When switched from an operating cryocooler to a non-operating cryocooler the heat burden may increase on the cryostat and the superconducting electrical machine due to a parasitic heat load that is transmitted, via cryogenic convection and conduction running within the cryocooler, through the cryocooler housing to the superconducting electrical machine. The problem with parasitic heat is worse when the cryocooler is in an angled orientation (as opposed to vertical orientation). The disclosed embodiments lower the helium gas pressure within the non-operating cryocooler via the removal of helium gas. In response, the respective temperatures of the cryostat and the superconducting electrical machine are lowered by reducing the heat burden. The disclosed embodiments enable a lower boil off for standard cryogenic systems during cooler outage or transport. The disclosed embodiments enable a longer ridethrough time for low cryogenic systems. The disclosed embodiments reduce a total helium inventory required for a low cryogenic system, thus, reducing cost.

The disclosed embodiments include a superconducting machine system including a superconducting electrical machine. The superconducting machine system also includes a cryogenic vessel. The cryogenic vessel encompasses the superconducting electrical machine. The superconducting machine further includes a vacuum vessel wall encompasses the cryogenic vessel. The superconducting machine system even further includes a cryocooler coupled to the vacuum vessel wall, wherein the cryocooler is configured to cool the superconducting electrical machine. The superconducting machine system still further includes a system configured, when the cryocooler is switched to a non-operative state, to remove helium gas from within a cryocooler housing to reduce a helium gas pressure within the cryocooler to minimize a parasitic heat load generated when the cryocooler is switched from an operative state to the non-operative state.

In certain embodiments, the system includes a vacuum pump that is configured, when the cryocooler is switched to the non-operative state, to remove the helium gas until the helium gas pressure is reduced to a set threshold. In certain embodiments, the set threshold is below 0.1 bar and is above 10⁻¹ millibar. In certain embodiments, the set threshold is between 10¹ millibar and 10¹⁰ millibar. In certain embodiments, the set threshold is below 0.1 bar and is above 10⁻¹⁰ millibar.

In certain embodiments, the vacuum pump is a roughing vacuum pump. In certain embodiments, the vacuum pump is a turbo-mechanical pump. In certain embodiments, the superconducting electrical machine is a superconducting magnet comprising superconducting coils. In certain embodiments, wherein the cryocooler is oriented at an angle when coupled to the vacuum vessel wall. In certain embodiments, the superconducting electrical machine is a superconducting generator.

In certain embodiments, the system, when the cryocooler is switched to the non-operative state, is configured to initially vent the helium gas from the cryocooler to reduce the helium gas pressure to a first set threshold. Then the vacuum pump is configured to remove the helium gas until the helium gas pressure is reduced to a second set threshold that is lower than the first set threshold.

In disclosed embodiments, a system for reducing (e.g., minimizing or eliminating) parasitic heat load from a non-operating cryocooler is provided. The system includes a cryocooler configured to couple to a vacuum vessel wall encompassing a cryogenic vessel encompassing a superconducting electrical machine, wherein the cryocooler is configured to cool the superconducting electrical machine. The system also includes a vacuum pump. The system further includes a controller including a memory and a processing system including one or more processors. The controller is configured to provide control signals to the vacuum pump, when the cryocooler is switched to a non-operative state, that cause the vacuum pump to remove helium gas from within a cryocooler housing to reduce a helium gas pressure within the cryocooler to minimize a parasitic heat load generated when the cryocooler is switched from an operative state to the non-operative state.

In certain embodiments, the system includes one or more temperature sensors coupled to the cryocooler. The controller is configured to receive feedback from the one or more temperature sensors, to determine an amount of the parasitic heat load generated when the cryocooler is switched from the operative state to the non-operative state based on the feedback, determine a specific helium gas pressure to achieve within the cryocooler based on the amount of the parasitic heat load, and to provide the control signals to the vacuum pump that cause the vacuum pump to remove the helium gas until the specific helium gas pressure is reached.

In certain embodiments, the controller is configured, when the cryocooler is switched to a non-operative state, to provide the control signals to a valve that causes initial venting of the helium gas from the cryocooler to reduce the helium gas pressure to a first set threshold, and then to provide the control signals to the vacuum pump, when the cryocooler is switched to a non-operative state, that cause the vacuum pump to remove the helium gas until the helium gas pressure is reduced to a second set threshold that is lower than the first set threshold. In certain embodiments, the controller is configured to provide the control signals to the vacuum pump, when the cryocooler is switched to a non-operative state, that cause the vacuum pump to remove the helium gas until the helium gas pressure is reduced to a set threshold.

In disclosed embodiments, a method for reducing (e.g., minimizing or eliminating) parasitic heat load from a non-operating cryocooler includes switching a cryocooler from an operative state to a non-operative state, wherein the cryocooler is coupled to a vacuum vessel wall encompassing a cryogenic vessel encompassing a superconducting electrical machine, and wherein the cryocooler is configured to cool the superconducting electrical machine. The method also includes utilizing a vacuum pump, when the cryocooler is switched to the non-operative state, to remove helium gas from within a cryocooler housing to reduce a helium gas pressure within the cryocooler to minimize a parasitic heat load generated when the cryocooler is switched from the operative state to the non-operative state.

In certain embodiments, the method includes providing control signals to a valve that cause initial venting of the helium gas from the cryocooler to reduce the helium gas pressure to a first set threshold, and then provide the control signals to the vacuum pump, when the cryocooler is switched to a non-operative state, that cause the vacuum pump to remove the helium gas until the helium gas pressure is reduced to a second set threshold that is lower than the first set threshold. In certain embodiments, the method includes providing control signals to the vacuum pump, when the cryocooler is switched to a non-operative state, that cause the vacuum pump to remove the helium gas until the helium gas pressure is reduced to a set threshold.

In certain embodiments, the method includes receiving feedback from one or more temperature sensors coupled to the cryocooler, determining an amount of the parasitic heat load generated when the cryocooler is switched from the operative state to the non-operative state based on the feedback, determining a specific helium gas pressure to achieve within the cryocooler based on the amount of the parasitic heat load, and providing control signals to the vacuum pump that cause the vacuum pump to remove the helium gas until the specific helium gas pressure is reached.

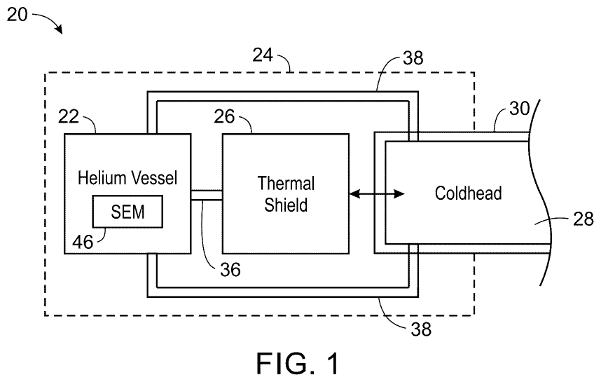

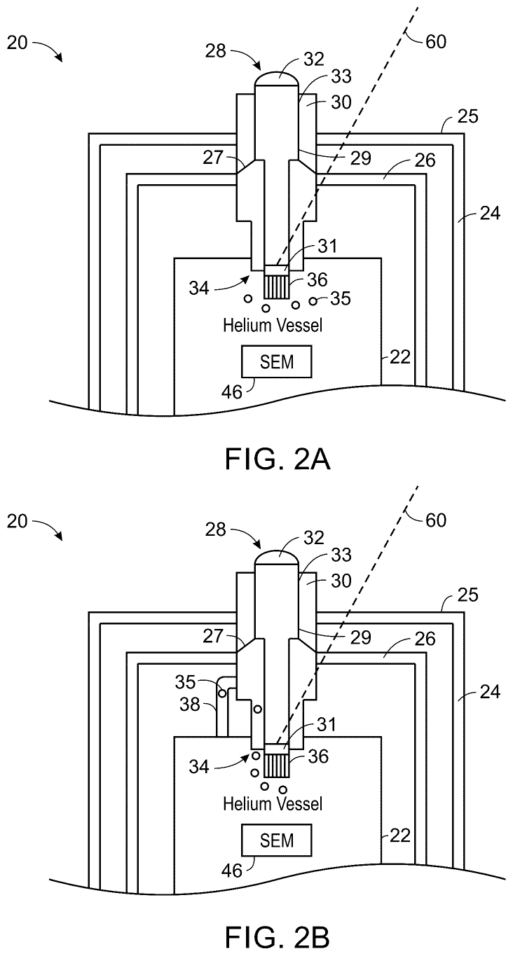

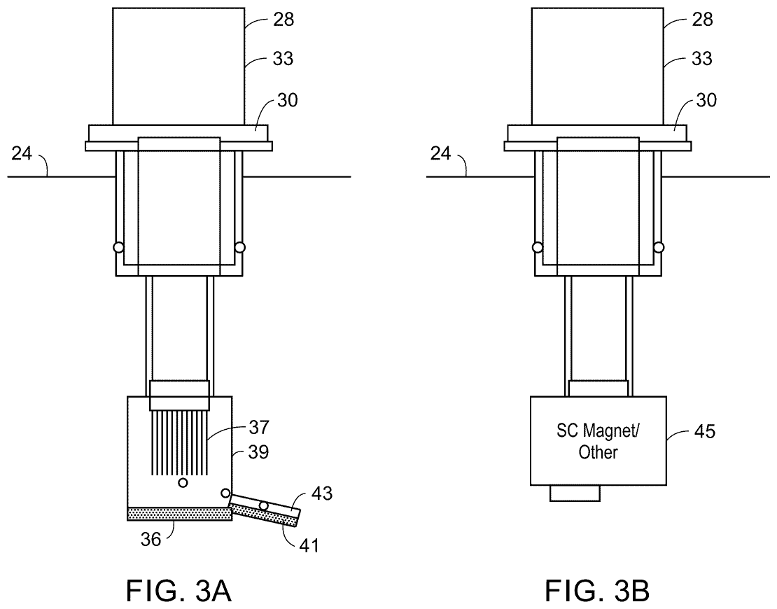

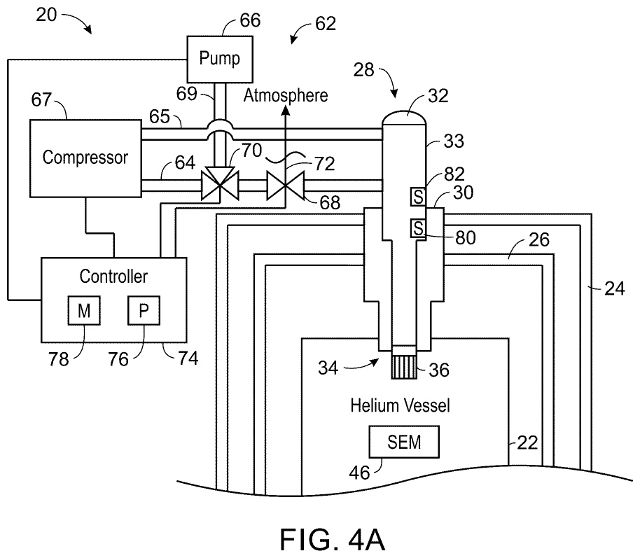

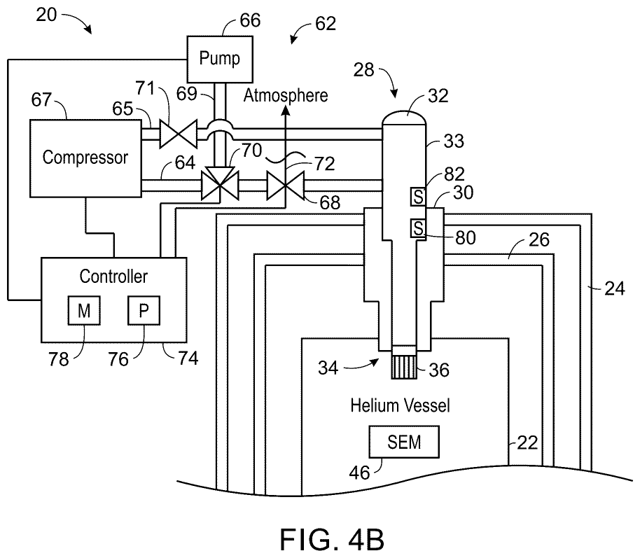

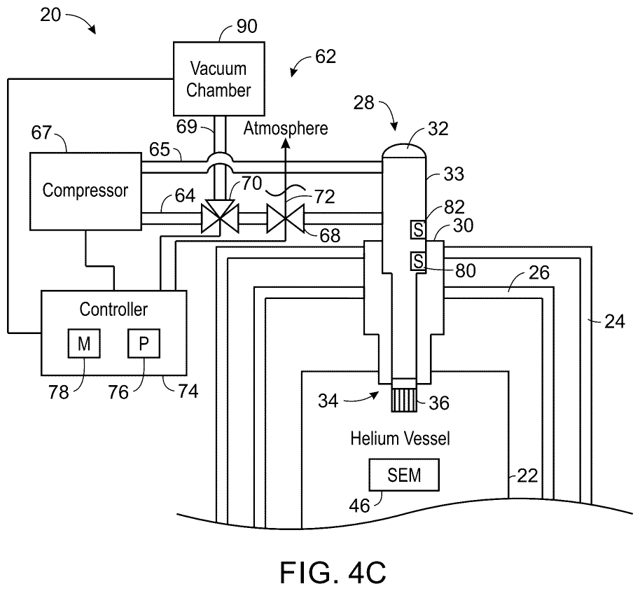

FIGS. 1, 2A, and 2B are simplified block diagrams illustrating superconducting machine system 20. The superconducting machine system 20 includes a superconducting electrical machine 46. In certain embodiments, the superconducting machine system is a superconducting magnet (e.g., of an MRI system or other type of system). In certain embodiments, the superconducting machine system is a superconducting generator or motor, or other type of superconducting system, such as in accelerator magnet technology, for superconducting RF cavity, or other. In certain embodiments, the superconducting electrical machine 46 includes a set of superconducting coils with their support structure. The superconducting machine system 20 includes a vessel 22 (e.g., cryogenic vessel) that holds a liquid cryogen, such as liquid helium. Thus, in this embodiment, the vessel 22 is a helium vessel, which also may be referred to as a helium pressure vessel. The vessel 22 is surrounded by a vacuum vessel 24 and includes a thermal shield 26 that encloses the vessel 22. The thermal shield 26 may be, for example, a thermally isolating radiation shield. A coldhead 28, which in various embodiments is a cryocooler, extends through the vacuum vessel 24 within a coldhead sleeve 30 (which is coupled to a wall 25 of the vacuum vessel 24). In certain embodiments, the superconducting machine system 20 may include a plurality of coldheads 28. The cold end of the coldhead 28 may be positioned within the coldhead sleeve 30 without affecting the vacuum within the vacuum vessel 24. The coldhead 28 is inserted (or received) and secured within the coldhead sleeve 30 using any suitable means, such as one or more flanges and bolts, or other means known in the art. In certain embodiments, the coldhead sleeve 30 is a vacuum sleeve in FIG. 2A. In FIG. 2A, thermal contact 27 occurs from the thermal shield 26 to the first stage 29 of the coldhead 28. In certain embodiments, the coldhead sleeve 30 is in a helium atmosphere. In certain embodiments, the coldhead 28 is run with the coldhead sleeve 30 filled with helium vapor as in FIG. 2B. In certain embodiments, the superconducting machine system 20 does not utilize a coldhead vacuum sleeve as depicted in FIG. 3A and FIG. 3B. FIG. 3A shows the coldhead 28 with attached liquefaction fins 37 of a liquefaction cup 39 for recondensing helium or other cryogens coupled to an inlet and an outlet 43. FIG. 3B shows the coldhead 28 directly attached to a superconducting magnet or other coldmass 45 without liquefying a cryogen. Moreover, a motor 32 of the coldhead 28 is provided outside the vacuum vessel 24 as shown in FIG. 4. The coldhead 28 includes a housing 33 that houses a piston drive mechanism and the regenerator material (not shown) so that a Gifford-McMahon (GM) cycle can be performed.

In certain embodiments, the coldhead 28 is a single stage cooler (e.g., operating at 20 Kelvin (K) or higher). In certain embodiments, the coldhead 28 is a two-stage cooler. For example, the coldhead 28 includes a first stage 29 and a second stage 31. The first stage 29 is coupled to the thermal shield 26. The second stage 31 is coupled to the vessel 22. The coldhead sleeve 30 includes an open end 34 into the helium vessel 22. As illustrated in FIG. 2A and FIG. 2B, the coldhead 28 in various embodiments includes a recondenser 36 at a lower end of the coldhead 28 having a portion thereof that extends into the helium vessel 22 through the open end 34 when the coldhead 28 is inserted and received within the coldhead sleeve 30. The recondenser 36 recondenses boiled off helium gas from the helium vessel 22. In FIGS. 2A and 2B, recondensing drops are indicated by reference numeral 35. In certain embodiments, as shown in FIG. 2B, a passageway 38 enables the liquefication of helium into open bottom 34 into the helium vessel 22.

In certain embodiments, the superconducting electrical machine is a magnet, which in various embodiments is a superconducting magnet, is provided inside the helium vessel 22 and is controlled during operation of an MRI system as described in more detail herein to acquire MRI image data. Additionally, during operation of the MRI system, liquid helium within the helium vessel 22 of the MRI magnet system cools the superconducting magnet, which may be configured as a coil assembly as is known. The superconducting magnet may be cooled, for example, to a superconducting temperature, such as 4.2 K or higher. The cooling process may include the recondensing of boiled off helium gas to liquid by the recondenser 36 and returned to the helium vessel 22. In certain embodiments, during operation of the coldhead 28, the temperature at the first stage 29 is approximately 45 Kelvin (K) and approximately 4 K at the second stage 31. The temperature of the first stage 29 and the second stage 31 may be different.

The coldhead 28 may include different internal components within the first and second stages 29, 31 (e.g., stainless steel meshes, piston, rare earth spheres, etc.). As depicted in FIGS. 2A and 2B, the coldhead 28 is coupled to the vacuum vessel 24 in a vertical orientation (i.e., the coldhead is perpendicular with respect to the wall 25 of the vacuum vessel 24 at a zero-degree orientation). When the coldhead 28 is switched to a non-operative state (i.e., off-state with coldhead 28 not cooling the superconducting electrical machine 46) from an operative state (i.e., on-state with coldhead 28 cooling the superconducting electrical machine 46), a heat burden is placed on the vessel 22 and the superconducting electrical machine 46 (e.g., superconducting magnet) that is higher than expected due to parasitic head load that is transferred, via cryogenic currents within the coldhead 28, through the coldhead housing 33 to the superconducting electrical machine 46. In certain embodiments, the coldhead 28 is arranged in an angled orientation (represented by dashed line 60) relative to wall 25 of the vacuum vessel 24. The angle of the coldhead 28 may be any orientation different from that depicted in FIG. 2. In the angled orientation, the parasitic heat load can be higher than vertical orientation. As described in greater detail below, the superconducting machine system 20 includes a system for lowering the helium gas pressure with the coldhead 28 by removing helium gas from the coldhead 28 when the coldhead 28 is switched to the non-operative state, thus, reducing (e.g., minimizing or eliminating) the parasitic heat load.

FIG. 4A is a cross-sectional view of a portion of the superconducting machine system 20 in FIGS. 1 and 2A and B having a system 62 for reducing (e.g., minimizing or eliminating) parasitic heat load (e.g., via a flexible return line). The superconducting machine system 20 is as described in FIGS. 1 and 2A and B. The system 62 is configured to lower the helium gas pressure within the coldhead 28 (i.e., within interior of coldhead 28) via removal of helium gas from the coldhead 28 to reduce (e.g., minimize or eliminate) the parasitic heat load generated when the coldhead 28 is switched to the non-operative state. The system 62 includes passageway 64 (return line) and passageway 65 (supply line) coupling a compressor 67 (which compresses the helium) to the coldhead 28. The system 62 includes a pump 66 (e.g., vacuum pump) coupled to the passageway 64 via passageway 69. In certain embodiments, the pump 66 is a roughing vacuum pump. The roughing vacuum pump is configured to achieve a vacuum range that extends to just above 10⁻³ mbar. In certain embodiments, the pump 66 is a turbomechanical pump. The turbomechanical pump is configured to achieve a vacuum range between 10⁻¹ mbar to 10⁻¹⁰ mbar. A vacuum range between atmospheric pressure and 1 mbar is known as rough vacuum. A vacuum range between 1 mbar and 10⁻³ mbar is known as a medium vacuum. The vacuum may also range from high to ultra-high through to extreme high vacuum ranges between 10⁻³ mbar and less than 10⁻¹² mbar.

Disposed along the passageway 64 is a valve 68 (e.g., three-way valve) and a valve 70 (e.g., three-way valve). Valve 70 is disposed between the valve 68 and the pump 66 and compressor 67. The number and arrangement of valves may vary. In certain embodiments, only a single valve may be utilized. The valve 68 is coupled to a passageway 72.

The system 62 includes a controller 74 including a processing system 76 (e.g., one or more processors) and a non-transitory memory 78. Methods for controlling the system 62 (i.e., the reduction (e.g., the minimization or elimination) of parasitic head load) may be stored as executable instructions in the non-transitory memory 78 and executed by the processing system 76.

As an example, the non-transitory memory 78 may store processor-executable software code or instructions (e.g., firmware or software), which are tangibly stored on a non-transitory computer readable medium. Additionally or alternatively, the non-transitory memory 78 may store data. As an example, the memory 154 may include a volatile memory, such as random-access memory (RAM), and/or a nonvolatile memory, such as read-only memory (ROM), flash memory, a hard drive, or any other suitable optical, magnetic, or solid-state storage medium, or a combination thereof. Furthermore, the processing system 76 may include multiple microprocessors, one or more “general-purpose” microprocessors, one or more special-purpose microprocessors, and/or one or more application specific integrated circuits (ASICS), or some combination thereof. For example, the processing system 76 may include one or more reduced instruction set (RISC) or complex instruction set (CISC) processors. The processing system 76 may include multiple processors, and/or the non-transitory memory 78 may include multiple memory devices.

The controller 74 is communicatively coupled to actuators of the pump 66, the compressor 67, valve 68, and valve 70. The controller 74 is configured to provide control signals to turn on or off the pump 66 or adjust a vacuum level of the pump 66. The controller 74 is configured to control the compressor 67. The controller 74 is configured to open or close the valves 68, 70. The controller 74 is configured to remove helium gas from the coldhead 28 to reduce (e.g., minimize or eliminate) a parasitic head load generated during the switching of the coldhead 28 to a non-operative state. In particular, in certain embodiments, upon the coldhead 28 being switched to the non-operative state, the controller 74 is configured, while valve 70 is closed and valve 68 is closed blocking flow toward valve 70, to provide control signals to open valve 68 to enable flow along the passageway 72 to vent helium gas to the atmosphere to lower the helium gas pressure to a first set or desired threshold (e.g., 1 bar). Upon lowering the helium gas pressure to the first set threshold, the controller 74 is configured to provide control signals to close the portion of the valve 68 to block flow along the passageway 72. Then, the controller 74 is configured to provide control signals to open the portion of valve 68 to enable flow along the passageway 64 toward valve 70, and to open valve 70 in the portion coupled to the pump 66 while the portion coupled to the compressor 67 is closed, and to turn on the pump 66 to apply a vacuum to further lower helium gas pressure in the coldhead 28 to a second set or desired threshold. In certain embodiments, the second set threshold may be lower than 1 bar but just above 10⁻³ mbar if roughing vacuum pump is utilized. In certain embodiments, the second set threshold may be between 10⁻¹ mbar to 10⁻¹⁰ mbar. In certain embodiments, the first and/or second set thresholds may vary. In certain embodiments, instead of initially venting helium gas, the controller 74 may utilize the pump 66 to lower the helium gas pressure to a set or desired threshold (via the return line).

In certain embodiments, the system 62 includes one or more temperature sensors 80 coupled the coldhead 28. The controller 74 is communicatively coupled to the temperature sensors 80 and configured to receive feedback from the temperature sensors 80. In certain embodiments, the controller 74 is configured to determine an amount of the parasitic heat load generated when the coldhead 28 is switched from the operative state to the non-operative state based on the feedback from the temperature sensors 80, to determine a specific helium gas pressure to achieve within the coldhead 28 based on the amount of the parasitic heat load, and to provide the control signals to the pump 66 that cause the pump 66 to remove the helium gas until a specific helium gas pressure is reached.

In certain embodiments, the system 62 includes one or more pressure sensors 82 within the coldhead 28. The controller 74 is configured to utilize the feedback from the pressure sensors 82 to monitor helium gas pressure within the coldhead 28 during removal of helium gas.

FIG. 4B is a cross-sectional view of a portion of the superconducting machine system 20 in FIGS. 1 and 2 having a system 62 for reducing (e.g., minimizing or eliminating) parasitic heat load (e.g., via the return line or supply line). The superconducting machine system 20 is as described in FIGS. 1 and 2. The system 62 is configured to lower the helium gas pressure within the coldhead 28 (i.e., within interior of coldhead 28) via removal of helium gas from the coldhead 28 to reduce (e.g., minimize or eliminate) the parasitic heat load generated when the coldhead 28 is switched to the non-operative state. The system 62 includes passageway 64 (return line) and passageway 65 (supply line) coupling a compressor 67 (which compresses the helium) to the coldhead 28. The system 62 includes a pump 66 (e.g., vacuum pump) coupled to the passageway 64 via passageway 69. Disposed along the passageway 64 is a valve 68 (e.g., three-way valve) and a valve 70 (e.g., three-way valve). Valve 70 is disposed between the valve 68 and the pump 66 and compressor 67. The number and arrangement of valves may vary. In certain embodiments, only a single valve may be utilized. The valve 68 is coupled to a passageway 72. Disposed along the passageway 65 is a valve 71. In certain embodiments, upon the coldhead 28 being switched to the non-operative state, the controller 74 is configured, while the valve 71 is closed, to control valve 70 to close to the passage 64 and open to passage 69. The controller 74 is then configured to turn on the pump 66 to pump out helium gas in the coldhead housing 33 to a preset or desired threshold (e.g. 10-1 mbar). In certain embodiments, the valve 70 and 71 are physically very close to the coldhead, therefore the amount of helium gas to be pumped out and wasted will be minimized. Majority of helium gas are still stored in the helium passage 64 and 65 and the compressor 67.

FIG. 4C shows another embodiment of the superconducting machine system 20 that has a vacuum chamber 90 connected to helium passage 64 through valve 70. The vacuum chamber has been pre-pumped to less than 10⁻¹ mbar vacuum pressure using a service vacuum pump tool. In certain embodiments, upon the coldhead 28 being switched to the non-operative state, the controller 74 is configured to control valve 70 to open to the passage 69 and the vacuum chamber 90, so helium gas inside the cryocooler housing 33 will be sucked into the vacuum chamber 90. Therefore, the helium pressure inside of the cryocooler housing 33 will be reduced and the heat load leaked from the non-operative cryocooler to the superconducting electrical machine 46 will be dramatically reduced. In certain embodiment, the volume of the vacuum chamber 90 will be 10 to 100 times larger than the volume of the cryocooler housing 33.

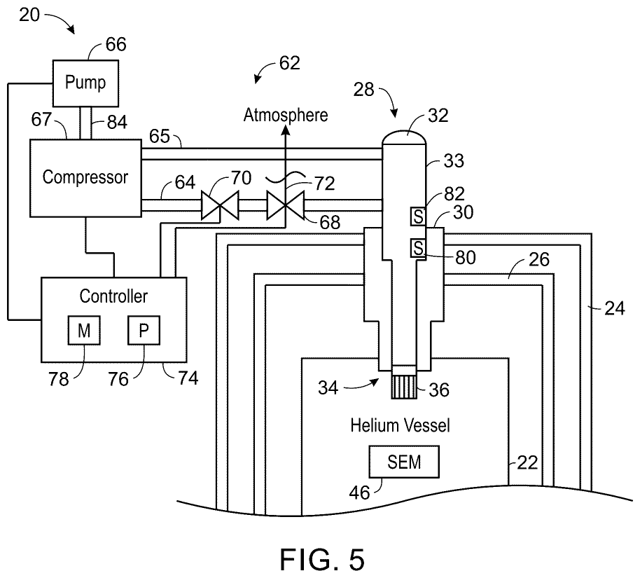

FIG. 5 is a cross-sectional view of a portion of the superconducting machine system 20 in FIGS. 1 and 2 having a system 62 for reducing (e.g., minimizing or eliminating) parasitic heat load (e.g., via the compressor 67). The superconducting machine system 20 is as described in FIGS. 1 and 2. The system 62 is configured to lower the helium gas pressure within the coldhead 28 via removal of helium gas from the coldhead 28 to reduce (e.g., minimize or eliminate) the parasitic heat load generated when the coldhead 28 is switched to the non-operative state. The system 62 includes passageway 64 (return line) and passageway 65 (supply line) coupling a compressor 67 (which compresses the helium) to the coldhead 28. In certain embodiments, the passageways 64, 65 are rigid. In certain embodiments, the passageways 64, 65 are flexible and modified to enable evacuation from the compressor end. In particular, the passageway 64 is coupled to a port on a compressor 84 of the coldhead 28. The system 62 includes a pump 66 (e.g., vacuum pump) coupled via passageway 84 to the compressor 67. In certain embodiments, the pump 66 is a roughing vacuum pump. The roughing vacuum pump is configured to achieve a vacuum range that extends to just above 10⁻³ mbar. In certain embodiments, the pump 66 is a turbo-mechanical pump. The turbo-mechanical pump is configured to achieve a vacuum range between 10⁻¹ mbar to 10⁻¹⁰ mbar. A vacuum range between atmospheric pressure and 1 mbar is known as rough vacuum. A vacuum between 1 mbar and 10⁻³ mbar is known as a medium vacuum. A vacuum from high to ultra-high through to extreme high vacuum ranges between 10⁻³ mbar and less than 10⁻¹² mbar.

Disposed along the passageway 64 is a valve 68 (e.g., three-way valve) and a valve 70 (e.g., two-way valve). Valve 70 is disposed between the valve 68 and the pump 66. The number and arrangement of valves may vary. In certain embodiments, only a single valve may be utilized. The valve 68 is coupled to a passageway 72.

The system 62 includes a controller 74 including a processing system 76 (e.g., one or more processors) and a non-transitory memory 78. Methods for controlling the system 62 (i.e., the reduction (e.g., the minimization or elimination) of parasitic head load) may be stored as executable instructions in the non-transitory memory 78 and executed by the processing system 76.

As an example, the non-transitory memory 78 may store processor-executable software code or instructions (e.g., firmware or software), which are tangibly stored on a non-transitory computer readable medium. Additionally, or alternatively, the non-transitory memory 78 may store data. As an example, the memory 154 may include a volatile memory, such as random-access memory (RAM), and/or a nonvolatile memory, such as read-only memory (ROM), flash memory, a hard drive, or any other suitable optical, magnetic, or solid-state storage medium, or a combination thereof. Furthermore, the processing system 76 may include multiple microprocessors, one or more “general-purpose” microprocessors, one or more special-purpose microprocessors, and/or one or more application specific integrated circuits (ASICS), or some combination thereof. For example, the processing system 76 may include one or more reduced instruction set (RISC) or complex instruction set (CISC) processors. The processing system 76 may include multiple processors, and/or the non-transitory memory 78 may include multiple memory devices.

The controller 74 is communicatively coupled to actuators of the pump 66, the compressor 67, valve 68, and valve 70. The controller 74 is configured to provide control signals to turn on or off the pump 66 or adjust a vacuum level of the pump 66. The controller 74 is configured to open or close the valves 68, 70. The controller 74 is configured to control the compressor 67. The controller 74 is configured to remove helium gas from the coldhead 28 to reduce (e.g., minimize or eliminate) a parasitic head load generated during the switching of the coldhead 28 to a non-operative state. In particular, in certain embodiments, upon the coldhead 28 being switched to the non-operative state, the controller 74 is configured, while valve 70 is closed and valve 68 is closed blocking flow toward valve 70, to provide control signals to open valve 68 to enable flow along the passageway 72 to vent helium gas to the atmosphere to lower the helium gas pressure to a first set or desired threshold (e.g., 1 bar). Upon lowering the helium gas pressure to the first set threshold, the controller 74 is configured to provide control signals to close the portion of the valve 68 to block flow along the passageway 72. Then, the controller 74 is configured to provide control signals to open the portion of valve 68 to enable flow along the passageway 64 toward valve 70 (and the compressor 67), to open valve 70, and to turn on the pump 66 to apply a vacuum to further lower helium gas pressure in the coldhead 28 to a second set or desired threshold by evacuating the compressor 67. In certain embodiments, the second set threshold may be lower than 1 bar but just above 10⁻³ mbar if roughing vacuum pump is utilized. In certain embodiments, the second set threshold may be between 10⁻¹ mbar to 10⁻¹⁰ mbar. In certain embodiments, the first and/or second set thresholds may vary. In certain embodiments, instead of initially venting helium gas, the controller 74 may utilize the pump 66 to lower the helium gas pressure to a set or desired threshold (via evacuating the compressor 67).

In certain embodiments, the system 62 includes one or more temperature sensors 80 coupled the coldhead 28. The controller 74 is communicatively coupled to the temperature sensors 80 and configured to receive feedback from the temperature sensors 80. In certain embodiments, the controller 74 is configured to determine an amount of the parasitic heat load generated when the coldhead 28 is switched from the operative state to the non-operative state based on the feedback from the temperature sensors 80, to determine a specific helium gas pressure to achieve within the coldhead 28 based on the amount of the parasitic heat load, and to provide the control signals to the pump 66 that cause the pump to remove the helium gas until a specific helium gas pressure is reached.

In certain embodiments, the system 62 includes one or more pressure sensors 82 within the coldhead 28. The controller 74 is configured to utilize the feedback from the pressure sensors 82 to monitor helium gas pressure within the coldhead 28 during removal of helium gas.

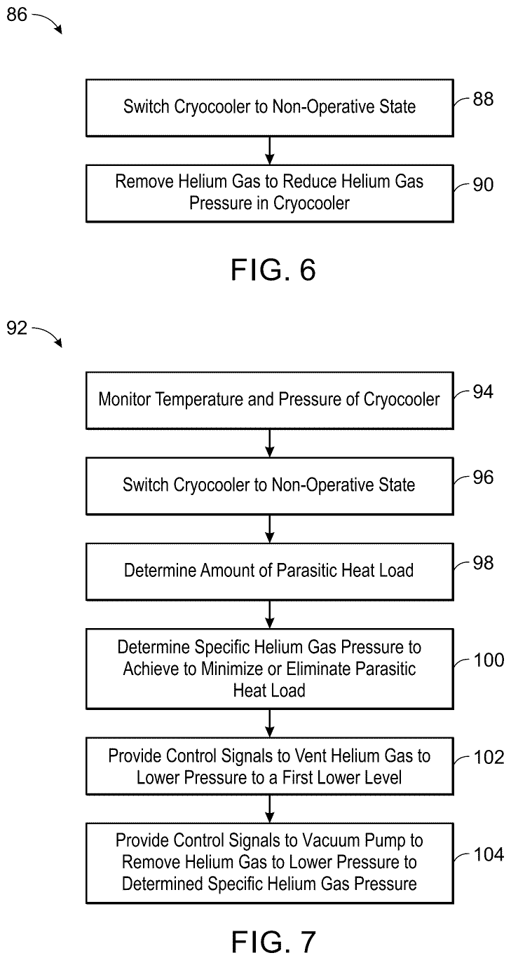

FIG. 6 is a flow chart of an embodiment of a method 86 for reducing (e.g., reducing or eliminating) parasitic heat load from a non-operating cryocooler (e.g., coldhead). One or more steps of the method 86 may be performed by one or more components of the system 62 (e.g., controller 74) and/or the superconducting machine system 20 in FIGS. 4 and 5.

The method 86 includes switching a cryocooler from an operative state to a non-operative state, wherein the cryocooler is coupled to a vacuum vessel wall encompassing a cryogenic vessel encompassing a superconducting electrical machine, and wherein the cryocooler is configured to cool the superconducting electrical machine (block 88). The method 86 also includes removing helium gas from within a cryocooler housing (e.g., utilizing system 62 in FIGS. 4 and 5) to reduce a helium gas pressure within the cryocooler to reduce (e.g., minimize or eliminate) a parasitic heat load generated when the cryocooler is switched from an operative state to the non-operative state (block 90).

FIG. 7 is a flow chart of an embodiment of a method 92 for reducing (e.g., minimizing) or eliminating parasitic heat load from a non-operating cryocooler (e.g., utilizing monitoring). One or more steps of the method 92 may be performed by one or more components of the system 62 (e.g., controller 74) and/or the superconducting machine system 20 in FIGS. 4 and 5.

The method 92 includes monitoring a temperature and a pressure of a cryocooler (block 94). Monitoring the temperature and a pressure of the cryocooler includes providing feedback to a controller from temperature sensors and pressure sensors coupled to the cryocooler. The method 92 also includes switching a cryocooler from an operative state to a non-operative state, wherein the cryocooler is coupled to a vacuum vessel wall encompassing a cryogenic vessel encompassing a superconducting electrical machine, and wherein the cryocooler is configured to cool the superconducting electrical machine (block 96). The method 92 includes determining (e.g., at the controller) an amount of the parasitic heat load generated when the cryocooler is switched from the operative state to the non-operative state based on the feedback from the temperature sensors (block 98). The method 92 also includes determining a specific helium gas pressure to achieve within the cryocooler (based on the amount of the parasitic heat load) to reduce (e.g., minimize or eliminate) the parasitic heat load (block 100). The method 92 further includes providing (e.g., via the controller) control signals (e.g., to a valve coupled to a passageway coupled to the cryocooler or a return line of the cryocooler) to vent helium gas (e.g., to the atmosphere) to lower the helium gas pressure from an initial level to a first lower level (e.g., preset or desired first threshold) in the cryocooler (while the cryocooler is in the non-operative state) (block 102). Subsequent to the venting (while the cryocooler is in the non-operative state), the method 92 includes providing (e.g., via the controller) the control signals to the vacuum pump (e.g., coupled to a port of a compressor of the cryocooler or a return line coupled to the cryocooler) that cause the vacuum pump to remove the helium gas until the specific helium gas pressure in the cryocooler is reached (block 104). In certain embodiments, the venting step may not occur and instead only the vacuum pump may be utilized to remove the helium gas to achieve the specific helium gas pressure.

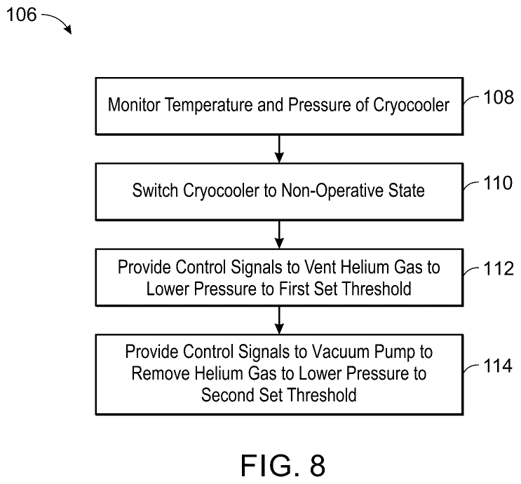

FIG. 8 is a flow chart of an embodiment of a method 106 for reducing (e.g., minimizing or eliminating) parasitic heat load from a non-operating cryocooler (e.g., utilizing set thresholds). One or more steps of the method 106 may be performed by one or more components of the system 62 (e.g., controller 74) and/or the superconducting machine system 20 in FIGS. 4 and 5.

The method 106 includes monitoring a temperature and a pressure of a cryocooler (block 108). Monitoring the temperature and a pressure of the cryocooler includes providing feedback to a controller from temperature sensors and pressure sensors coupled to the cryocooler. The method 106 also includes switching a cryocooler from an operative state to a non-operative state, wherein the cryocooler is coupled to a vacuum vessel wall encompassing a cryogenic vessel encompassing a superconducting electrical machine, and wherein the cryocooler is configured to cool the superconducting electrical machine (block 110). The method 92 further includes providing (e.g., via the controller) control signals (e.g., to a valve coupled to a passageway coupled to the cryocooler or a return line of the cryocooler) to vent helium gas (e.g., to the atmosphere) to lower the helium gas pressure from an initial level to a first set or desired threshold in the cryocooler (while the cryocooler is in the non-operative state) (block 112). Subsequent to the venting (while the cryocooler is in the non-operative state), the method 106 includes providing the control signals (e.g., via the controller) to the vacuum pump (e.g., coupled to a port of a compressor of the cryocooler or a return line coupled to the cryocooler) that cause the vacuum pump to remove the helium gas until the helium gas pressure is reduced to a second set threshold in the cryocooler that is lower than the first set threshold (block 114).

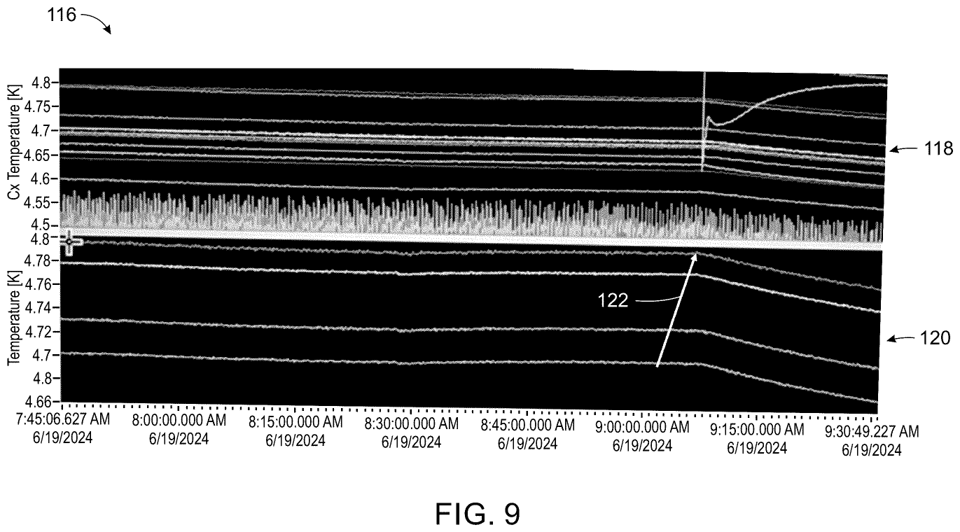

FIG. 9 is an example screenshot 116 of temperatures in a cryostat and a superconducting magnet of an MRI system. A top graph 118 depicts temperatures at different locations of the cryostat over time. A bottom graph 120 depicts temperatures at different locations of the superconducting magnet over time. The temperatures are during a time period where a cryocooler is in a non-operative state. Upon the removal of helium gas from the cryocooler (utilizing the techniques described above), temperatures at the superconducting magnet trend significantly downward as indicated by arrow 122. Similarly, at the same timepoint, the temperatures at the cryostat also trend significantly downward as shown in the top graph 118.

Once the cryocooler stops due to a fault or a power outage the pressure in the cryocooler is also shown on the compressor pressure gauge, now showing a static pressure rather a dynamic pressure. The static pressure is the pressure in the cryocooler with attached connecting lines, and in the compressor. In principle, once a power outage or compressor failure happens, the vacuum pump can work using a battery pack or other. The vacuum pump does need to work only for a very short time since the helium volume in the cryocooler or in the cryocooler with attached gas lines is small.

It should be noted that the superconducting electric machines (e.g., superconducting magnet, superconducting generator, etc.) may utilize multiple cryocoolers. In cases where more than one cryocooler may be out of operation the parasitic heat load may be greater (e.g., for 3 coolers that lose power the parasitic heat flux triples. Utilizing the above techniques one or more of the cryocoolers may be non-operative while enabling the superconducting electrical machines to be utilized or maintained in a superconducting state.

As discussed herein, the disclosed systems and methods are utilized with a wet system (which is a closed or sealed system) where the magnet is bath cooled or cooled with helium as a medium using thermosiphon technology or other. The disclosed systems and methods may also be utilized with applications where a cryocooler is directly mounted onto a superconducting coil with no helium involved for cooling (i.e., conduction cooled systems or sealed systems, or completely dry systems). For these, a cryocooler outage or cryocooler failure is very critical since there is an immediate spike in temperature, leading to a magnet quench (loss of superconducting state), if the cryocooler is not evacuated.

It should be noted that although some embodiments may be described in connection with superconducting magnets for MRI systems, the various embodiments may be implemented in connection with any type of system having superconducting magnets. The superconducting magnets may be implemented in other types of medical imaging devices, as well as non-medical imaging devices.

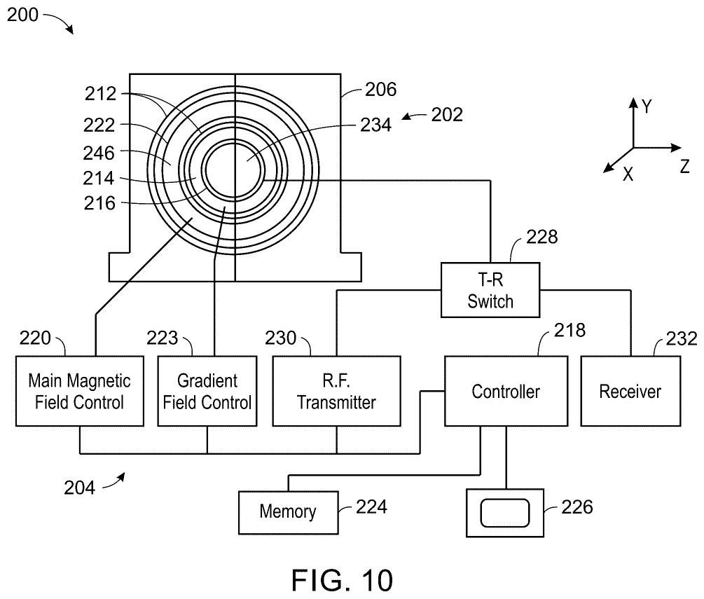

Thus, the various embodiments may be implemented in connection with different types of superconducting coils, such as superconducting coils for an MRI system. For example, the various embodiments may be implemented with superconducting coils for use with the MRI system 200 shown in FIG. 10. It should be appreciated that although the system 200 is illustrated as a single modality imaging system, the various embodiments may be implemented in or with multi-modality imaging systems. The system 200 is illustrated as an MRI imaging system and may be combined with different types of medical imaging systems, such as a computed tomography (CT), positron emission tomography (PET), a single photon emission computed tomography (SPECT), as well as an ultrasound system, or any other system capable of generating images, particularly of a human. Moreover, the various embodiments are not limited to medical imaging systems for imaging human subjects, but may include veterinary or non-medical systems for imaging non-human objects, luggage, etc.

Referring to FIG. 10, the MRI system 200 generally includes an imaging portion 202 and a processing portion 204 that may include a processor or other computing or controller device. The MRI system 200 includes within a gantry 206 a superconducting magnet 246 formed from coils, which may be supported on a magnet coil support structure. The helium vessel 222 surrounds the superconducting magnet 246 and is filled with liquid helium. The liquid helium may be used to cool a coldhead sleeve and coldhead housing and/or a thermal shield as described in more detail herein.

Thermal insulation 212 is provided surrounding the outer surface of the helium vessel 222 and the inner surface of the superconducting magnet 246. A plurality of magnetic gradient coils 214 are provided inside the superconducting magnet 246 and an RF transmit coil 216 is provided within the plurality of magnetic gradient coils 214. In some embodiments, the RF transmit coil 216 may be replaced with a transmit and receive coil. The components within the gantry 206 generally form the imaging portion 202. It should be noted that although the superconducting magnet 246 is a cylindrical shape, other shapes of magnets can be used.

The processing portion 204 generally includes a controller 218, a main magnetic field control 220, a gradient field control 223, a memory 224, a display device 226, a transmit-receive (T-R) switch 228, an RF transmitter 230 and a receiver 232.

In operation, a body of an object, such as a patient or a phantom to be imaged, is placed in the bore 234 on a suitable support, for example, a patient table. The superconducting magnet 246 produces a uniform and static main magnetic field Bo across the bore 234. The strength of the electromagnetic field in the bore 234 and correspondingly in the patient, is controlled by the controller 218 via the main magnetic field control 220, which also controls a supply of energizing current to the superconducting magnet 246.

The magnetic gradient coils 214, which include one or more gradient coil elements, are provided so that a magnetic gradient can be imposed on the magnetic field Bo in the bore 234 within the superconducting magnet 246 in any one or more of three orthogonal directions x, y, and z. The magnetic gradient coils 214 are energized by the gradient field control 223 and are also controlled by the controller 218.

The RF transmit coil 216, which may include a plurality of coils, is arranged to transmit magnetic pulses and/or optionally simultaneously detect MR signals from the patient if receive coil elements are also provided, such as a surface coil configured as an RF receive coil. The RF receive coil may be of any type or configuration, for example, a separate receive surface coil. The receive surface coil may be an array of RF coils provided within the RF transmit coil 216.

The RF transmit coil 216 and the receive surface coil are selectably interconnected to one of the RF transmitter 230 or receiver 232, respectively, by the T-R switch 228. The RF transmitter 130 and T-R switch 228 are controlled by the controller 218 such that RF field pulses or signals are generated by the RF transmitter 230 and selectively applied to the patient for excitation of magnetic resonance in the patient. While the RF excitation pulses are being applied to the patient, the T-R switch 228 is also actuated to disconnect the receive surface coil from the receiver 232.

Following application of the RF pulses, the T-R switch 228 is again actuated to disconnect the RF transmit coil 216 from the RF transmitter 230 and to connect the receive surface coil to the receiver 232. The receive surface coil operates to detect or sense the MR signals resulting from the excited nuclei in the patient and communicates the MR signals to the receiver 232. These detected MR signals are in turn communicated to the controller 218. The controller 218 includes a processor (e.g., image reconstruction processor), for example, that controls the processing of the MR signals to produce signals representative of an image of the patient.

The processed signals representative of the image are also transmitted to the display device 226 to provide a visual display of the image. Specifically, the MR signals fill or form a k-space that is Fourier transformed to obtain a viewable image. The processed signals representative of the image are then transmitted to the display device 226.

Technical effects of the disclosed subject matter include lowering the helium gas pressure within the non-operating cryocooler via the removal of helium gas. In response, the respective temperatures of the cryostat and the superconducting electrical machine are lowered, thus, reducing the heat burden. Technical effects of the disclosed subject matter include enabling a lower boil off for standard cryogenic systems during cooler outage or transport. Technical effects of the disclosed subject matter include enabling a longer ridethrough time for low cryogenic systems. Technical effects of the disclosed subject matter include reducing a total helium inventory required for a low cryogenic system, thus, reducing cost.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function]. . . ” or “step for [perform]ing [a function]. . . ”, it is intended that such elements are to be interpreted under 35 U.S.C. 112(f). However, for any claims containing elements designated in any other manner, it is intended that such elements are not to be interpreted under 35 U.S.C. 112(f).

The disclosure also provides support for a superconducting machine system, comprising: a superconducting electrical machine; a cryogenic vessel encompassing the superconducting electrical machine; a vacuum vessel wall encompassing the cryogenic vessel; a cryocooler coupled to the vacuum vessel wall, wherein the cryocooler is configured to cool the superconducting electrical machine; and a system configured, when the cryocooler is switched to a non-operative state, to remove helium gas from within a cryocooler housing to reduce a helium gas pressure within the cryocooler to minimize a parasitic heat load generated when the cryocooler is switched from an operative state to the non-operative state. In a first example of the superconducting machine system, the system comprises a vacuum pump that is configured, when the cryocooler is switched to the non-operative state, to remove the helium gas until the helium gas pressure is reduced to a set threshold. In a second example of the system, optionally including the first example, the set threshold is below 0.1 bar and is above 10⁻¹⁰ millibar. In a third example of the system, optionally including one or both of the first and second examples, the vacuum pump comprises a roughing vacuum pump. In a fourth example of the system, optionally including one or more or each of the first through third examples, the vacuum pump comprises a turbomechanical pump. In a fifth example of the system, optionally including one or more or each of the first through fourth examples, the system, when the cryocooler is switched to the non-operative state, is configured to initially vent the helium gas from the cryocooler to reduce the helium gas pressure to a first set threshold, and then the vacuum pump is configured to remove the helium gas until the helium gas pressure is reduced to a second set threshold that is lower than the first set threshold. In a sixth example of the system, optionally including one or more or each of the first through fifth examples, the system comprises a pre-evacuated vacuum chamber that is configured to remove helium gas from the cryocooler housing when the cryocooler is switched to the non-operative state. In a seventh example of the system, optionally including one or more or each of the first through sixth examples, the superconducting electrical machine comprises a superconducting magnet. In an eighth example of the system, optionally including one or more or each of the first through seventh examples, the cryocooler is oriented at an angle when coupled to the vacuum vessel wall. In a ninth example of the system, optionally including one or more or each of the first through eighth examples, the cryocooler is a single stage cooler. In a tenth example of the system, optionally including one or more or each of the first through the ninth examples, a cooling medium for the superconducting machine is any other cryogen. In an eleventh example of the system, optionally including one or more or each of the first through tenth examples, the superconducting electrical machine comprises a superconducting generator.

The disclosure also provides support for a system for reducing (e.g., reducing or eliminating) parasitic heat load from a non-operating cryocooler, comprising: a cryocooler configured to couple to a vacuum vessel wall encompassing a cryogenic vessel encompassing a superconducting electrical machine, wherein the cryocooler is configured to cool the superconducting electrical machine; a vacuum pump; and a controller comprising a memory and a processing system comprising one or more processors, wherein the controller is configured to provide control signals to the vacuum pump, when the cryocooler is switched to a non-operative state, that cause the vacuum pump to remove helium gas from within a cryocooler housing to reduce a helium gas pressure within the cryocooler to minimize a parasitic heat load generated when the cryocooler is switched from an operative state to the non-operative state. In a first example of the system, the system further comprises one or more temperature sensors coupled to the cryocooler, wherein the controller is configured to receive feedback from the one or more temperature sensors, to determine an amount of the parasitic heat load generated when the cryocooler is switched from the operative state to the non-operative state based on the feedback, determine a specific helium gas pressure to achieve within the cryocooler based on the amount of the parasitic heat load, and to provide the control signals to the vacuum pump that cause the vacuum pump to remove the helium gas until the specific helium gas pressure is reached. In a second example of the system, optionally including the first example, the controller is configured, when the cryocooler is switched to a non-operative state, to provide the control signals to a valve that cause initial venting of the helium gas from the cryocooler to reduce the helium gas pressure to a first set threshold, and then provide the control signals to the vacuum pump, when the cryocooler is switched to a non-operative state, that cause the vacuum pump to remove the helium gas until the helium gas pressure is reduced to a second set threshold that is lower than the first set threshold. In a third example of the system, optionally including one or both of the first and second examples, the controller is configured to provide the control signals to the vacuum pump, when the cryocooler is switched to a non-operative state, that cause the vacuum pump to remove the helium gas until the helium gas pressure is reduced to a set threshold. In a fourth example of the system, optionally including one or more or each of the first through third examples, the set threshold is below 0.1 bar and is above 10⁻¹ millibar. In a fifth example of the system, optionally including one or more or each of the first through fourth examples, the set threshold is between 10⁻¹ millibar and 10⁻¹⁰ millibar. In a sixth example of the system, optionally including one or more or each of the first through fifth examples, the superconducting electrical machine comprises a superconducting magnet. In a seventh example of the system, optionally including one or more or each of the first through sixth examples, the superconducting electrical machine comprises a superconducting generator. In an eighth example of the system, optionally including one or more or each of the first through seventh examples, the vacuum pump comprises a roughing vacuum pump or a turbomechanical pump.

The disclosure also provides support for a method for (e.g., reducing or eliminating) parasitic heat load from a non-operating cryocooler, comprising: switching a cryocooler from an operative state to a non-operative state, wherein the cryocooler is coupled to a vacuum vessel wall encompassing a cryogenic vessel encompassing a superconducting electrical machine, and wherein the cryocooler is configured to cool the superconducting electrical machine; and utilizing a vacuum pump, when the cryocooler is switched to the non-operative state, to remove helium gas from within a cryocooler housing to reduce a helium gas pressure within the cryocooler to minimize a parasitic heat load generated when the cryocooler is switched from the operative state to the non-operative state.

This written description uses examples to disclose the present subject matter, including the best mode, and also to enable any person skilled in the art to practice the subject matter, including making and using any devices or systems and performing any incorporated methods. The patentable scope of the subject matter is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

1. A superconducting machine system, comprising:
a superconducting electrical machine;
a cryogenic vessel encompassing the superconducting electrical machine;
a vacuum vessel wall encompassing the cryogenic vessel;
a cryocooler coupled to the vacuum vessel wall, wherein the cryocooler is configured to cool the superconducting electrical machine; and
a system configured, when the cryocooler is switched to a non-operative state, to remove helium gas from within a cryocooler housing to reduce a helium gas pressure within the cryocooler to minimize a parasitic heat load generated when the cryocooler is switched from an operative state to the non-operative state.

2. The superconducting machine system of claim 1, wherein the system comprises a vacuum pump that is configured, when the cryocooler is switched to the non-operative state, to remove the helium gas until the helium gas pressure is reduced to a set threshold.

3. The superconducting machine system of claim 2, wherein the set threshold is below 0.1 bar and is above 10⁻¹⁰ millibar.

4. The superconducting machine system of claim 2, wherein the vacuum pump comprises a roughing vacuum pump.

5. The superconducting machine system of claim 2, wherein the vacuum pump comprises a turbo-mechanical pump.

6. The superconducting machine system of claim 2, wherein the system, when the cryocooler is switched to the non-operative state, is configured to initially vent the helium gas from the cryocooler to reduce the helium gas pressure to a first set threshold, and then the vacuum pump is configured to remove the helium gas until the helium gas pressure is reduced to a second set threshold that is lower than the first set threshold.

7. The superconducting machine system of claim 1, comprising a pre-evacuated vacuum chamber that is configured to remove helium gas from the cryocooler housing when the cryocooler is switched to the non-operative state.

8. The superconducting machine system of claim 1, wherein the superconducting electrical machine comprises a superconducting magnet.

9. The superconducting machine system of claim 1, wherein the cryocooler is oriented at an angle when coupled to the vacuum vessel wall.

10. The superconducting machine of claim 1, wherein the cryocooler is a single stage cooler.

11. The superconducting machine of claim 1, wherein a cooling medium for the superconducting machine system is any other cryogen.

12. The superconducting machine system of claim 1, wherein the superconducting electrical machine comprises a superconducting generator.

13. A system for reducing parasitic heat load from a non-operating cryocooler, comprising:
a cryocooler configured to couple to a vacuum vessel wall encompassing a cryogenic vessel encompassing a superconducting electrical machine, wherein the cryocooler is configured to cool the superconducting electrical machine;
a vacuum pump; and
a controller comprising a memory and a processing system comprising one or more processors, wherein the controller is configured to provide control signals to the vacuum pump, when the cryocooler is switched to a non-operative state, that cause the vacuum pump to remove helium gas from within a cryocooler housing to reduce a helium gas pressure within the cryocooler to minimize a parasitic heat load generated when the cryocooler is switched from an operative state to the non-operative state.

14. The system of claim 13, further comprising one or more temperature sensors coupled to the cryocooler, wherein the controller is configured to receive feedback from the one or more temperature sensors, to determine an amount of the parasitic heat load generated when the cryocooler is switched from the operative state to the non-operative state based on the feedback, determine a specific helium gas pressure to achieve within the cryocooler based on the amount of the parasitic heat load, and to provide the control signals to the vacuum pump that cause the vacuum pump to remove the helium gas until the specific helium gas pressure is reached.

15. The system of claim 13, wherein the controller is configured, when the cryocooler is switched to a non-operative state, to provide the control signals to a valve that cause initial venting of the helium gas from the cryocooler to reduce the helium gas pressure to a first set threshold, and then provide the control signals to the vacuum pump, when the cryocooler is switched to a non-operative state, that cause the vacuum pump to remove the helium gas until the helium gas pressure is reduced to a second set threshold that is lower than the first set threshold.

16. The system of claim 13, wherein the controller is configured to provide the control signals to the vacuum pump, when the cryocooler is switched to a non-operative state, that cause the vacuum pump to remove the helium gas until the helium gas pressure is reduced to a set threshold.

17. The system of claim 16, wherein the set threshold is below 0.1 bar and is above 10⁻¹⁰ millibar.

18. The system of claim 17, wherein the set threshold is between 10⁻¹ millibar and 10⁻¹⁰ millibar.

19. The system of claim 13, wherein the superconducting electrical machine comprises a superconducting magnet.

20. The system of claim 13, wherein the superconducting electrical machine comprises a superconducting generator.

21. The system of claim 13, wherein the vacuum pump comprises a roughing vacuum pump or a turbomechanical pump.

22. A method for reducing parasitic heat load from a non-operating cryocooler, comprising:
switching a cryocooler from an operative state to a non-operative state, wherein the cryocooler is coupled to a vacuum vessel wall encompassing a cryogenic vessel encompassing a superconducting electrical machine, and wherein the cryocooler is configured to cool the superconducting electrical machine; and
utilizing a vacuum pump, when the cryocooler is switched to the non-operative state, to remove helium gas from within a cryocooler housing to reduce a helium gas pressure within the cryocooler to minimize a parasitic heat load generated when the cryocooler is switched from the operative state to the non-operative state.
